(19) United States
(12) Patent Application Publication
(10) Pub. No.: US 2016/0155965 A1
(43) Pub. Date: Jun. 2, 2016

(54) DISPLAY DEVICES AND METHODS OF USING THE SAME

(71) Applicant: EMPIRE TECHNOLOGY DEVELOPMENT LLC, Wilmington, DE (US)

(72) Inventor: Takahisa KUSUURA, Tokyo (JP)

(21) Appl. No.: 14/787,476

(22) PCT Filed: Jun. 11, 2013
(86) PCT No.: PCT/US13/45180

§ 371 Date: Oct. 28, 2015

(51) Int. Cl. H01L 51/00; G06F 3/041; B65H 16/02; H05K 3/22; H05K 1/02

(52) U.S. Cl. CPC H01L 51/0097; H05K 3/22; H05K 1/02; B65H 16/021; G06F 3/0412; H01L 2251/5338

(57) ABSTRACT

Disclosed herein are display devices including a flexible electronic display layer that is configured to emit an image. The flexible electronic display layer can, for example, be configured to releasably couple with a flexible supporting layer to increase stiffness of the flexible electronic display layer. Methods of making and using the display devices are also disclosed.

### BACKGROUND

Unless otherwise indicated herein, the materials described in this section are not prior art to the claims in this application and are not admitted to be prior art by inclusion in this section.

Ultra-thin flexible electronic display film technology is promising in terms providing portability for large displays. The flexible display can be of various designs and technological features include OLED, LEP, E-Ink, flexible LCD, and the like. The flexible display can be rolled or folded into a compact configuration, and then expanded when used for viewing.

### SUMMARY

Some embodiments disclosed herein are related to a display device. The display device can include: a flexible electronic display layer comprising a first side configured to emit an image and a second side comprising a first section configured to releasably couple a second section to increase stiffness of the flexible electronic display device. The display device can also include: a flexible supporting layer comprising a first side; and a flexible electronic display layer comprising: a first side configured to emit an image; and a second side configured to releasably couple with the first side of the flexible supporting layer to increase stiffness of the flexible electronic display layer.

In some embodiments, the flexible supporting layer comprises a first patterned array of projections on the first side of the flexible supporting layer; the second side of the flexible electronic display layer comprises a second patterned array of projections: and the first patterned array of projections on the first side of the flexible supporting layer is configured to releasably engage the second patterned array of projections on the second side of the flexible electronic display layer to increase stiffness of the flexible electronic display layer.

In some embodiments, at least one of the first patterned array of projections and the second patterned array of projections comprises projections having a cylindrical shape, a cuboidal shape, a polyhedral shape, a rectangular prism shape, a triangular prism shape, or a hexagonal prism shape. In some embodiments, at least one of the first patterned array of projections and the second patterned array of projections comprises straight bands. In some embodiments, at least one of the first patterned array of projections and the second patterned array of projections comprises curved bands.

In some embodiments, the projections in at least one of the first patterned array of projections and the second patterned array of projections have a width of about 1 nm to about 5 mm. In some embodiments, the projections in at least one of the first patterned array of projections and the second patterned array of projections have a thickness of about 10 nm to about 5 mm.

In some embodiments, the projections in the first patterned array of projections have about the same shape and dimensions as the projections in the second patterned array of projections.

In some embodiments, at least one of the first patterned array of projections and the second patterned array of projections have projections comprising a resin. In some embodiments, the resin comprises one or more of a rubber, a polyester, polystyrene, polytetrafluoroethylene, acrylonitrile butadiene styrene, polyolefins, polyethylene, polypropylene, polyvinyl chloride, polyamide, polyimide, polysulfone, polyetherketone, a liquid crystal polymer, polybenzimidazole, polyurethane, phenol resin, epoxy resin, silicon resin, acrylics, polyethylene terephthalate, a polycarbonate, a polycyclolefin, a polyimide, and copolymers thereof.

In some embodiments, at least one of the first patterned array of projections and the second patterned array of projections have porous projections. In some embodiments, at least one of the first patterned array of projections and the second patterned array of projections have hollow projections,

In some embodiments, at least one of the first patterned array of projections and the second patterned array of projections have projections comprising an electrorheological fluid or a magnetorheological fluid encapsulated in a resin. In some embodiments, at least one of the first patterned array of projections and the second patterned array of projections have a rhombic lattice, a hexagonal lattice, a square lattice, a rectangular lattice, or a parallelogrammic lattice.

In some embodiments, the first patterned array of projections has about the same lattice as the second patterned array of projections.

In some embodiments, at least one of the first side of the flexible supporting layer and the second side of the flexible electronic display layer comprises a release surface; and at least one of the first side of the flexible supporting layer and the second side of the flexible electronic display layer comprises an adhesive.

In some embodiments, the release surface is siliconized. In some embodiments, the release surface comprises a fluoropolymer.

In some embodiments, the adhesive is a pressure-sensitive adhesive.

In some embodiments, at least one of the first side of the flexible supporting layer and the second side of the flexible electronic display layer comprises one or more male engaging members, and at least one of the first side of the flexible supporting layer and the second side of the flexible electronic display layer comprises one or more female engaging member configured to releasably engage the one or more male engaging members.

In some embodiments, the one or more female engaging members comprise one or more loops, and wherein the one or more male engaging members comprise one or more hooks Con figured to releasably engage the one or more loops.

In some embodiments, the display device comprises hook-and-loop fasteners.

In some embodiments, the one or more female engaging members have a concave surface, and wherein the one or more male engaging members have a convex surface configured to releasably engage the concave surface of the one or more female engaging members.

In some embodiments, the first side of the flexible supporting layer comprises one or more suction cups configured to releasably adhere the second side of the flexible electronic display layer. In some embodiments, the second side of the flexible electronic display layer comprises one or more suction cups configured to releasably adhere the first side of the flexible supporting layer.

In some embodiments, the display device further comprises a second flexible supporting layer, the second flexible supporting layer comprising a first side configured to releasably engage a second side of the flexible supporting layer.

In some embodiments, the first side of the flexible supporting layer comprises one or more first magnetized regions have a first polarity; the second side of the flexible electronic display layer comprises one or more second magnetized regions have a second polarity; and the first magnetized regions on the first side of the flexible supporting layer are configured to releasably couple with the second magnetized regions on the second side of the flexible electronic layer.

In some embodiments, the first side of the flexible supporting layer comprises one or more first charged regions have a first charge; the second side of the flexible electronic display layer comprises one or more second charged regions have a second charge; and the first charged regions on the first side of the flexible supporting layer are configured to releasably couple with the second charged regions on the second side of the flexible electronic layer.

In some embodiments, the flexible electronic display layer and the flexible supporting layer are rotatably coupled. In some embodiments, the flexible electronic display layer and the flexible supporting layer are rotatably coupled about a hinge.

In some embodiments, the flexible electronic display layer comprises an organic electroluminescent display or an electro-optical display.

In some embodiments, the display device further comprises: a first roller, wherein the flexible electronic display layer is at least partially wound around the first roller; and a second roller, wherein the flexible supporting layer is at least partially wound around the second roller, wherein the display device is configured so that the first side of the flexible supporting layer engages the second side of the flexible electronic display layer while unwinding the flexible electronic display layer from the first roller.

In some embodiments, the first side of the flexible electronic display layer is coupled to the first roller at a first end of the flexible displayer layer, and a second side of the flexible supporting layer is coupled to the second roller at a first end of the flexible supporting layer.

In some embodiments, a second end of the flexible electronic display layer is coupled to a second end of the flexible supporting layer.

In some embodiments, the first roller is configured to rotate about a first axis, the second roller is configured to rotate about a second axis, and the first axis is generally parallel with the second axis.

In some embodiments, the display device further comprises a housing having at least one opening, wherein the first roller and the second roller are disposed within the housing, and wherein the flexible electronic display layer is configured to be withdrawn from the housing through the opening of the housing.

In some embodiments, at least one of the first roller and the second roller are spring loaded. In some embodiments, at least one of the first roller and the second roller comprises a ratchet.

In some embodiments, the flexible electronic, display layer and the flexible support layer are at least partially joined at one side edge so that the flexible electronic display layer is rotatable about the side edge to switch between a first configuration where the first side of the flexible electronic display layer is interfaced with the second side of the flexible support layer, and a second configuration were the first side of the flexible supporting layer is engaged with the second side of the flexible electronic display layer.

Some embodiments disclosed herein are related to a method of using a display device. The method can include: providing a display device comprising: a flexible supporting layer comprising a first side; and a flexible electronic display layer comprising a first side configured to emit an image and a second side configured to releasably couple with the first side of the flexible supporting layer to increase stiffness of the flexible electronic display layer; and engaging the first side of the flexible supporting layer with the second side of the flexible electronic display layer.

In some embodiments, the method further comprises disengaging the first side of the flexible supporting layer from the second side of the flexible electronic display layer. In some embodiments, engaging the first side of the flexible supporting layer with the second side of the flexible electronic display comprises: unwinding the flexible electronic display layer from a first roller; and unwinding the flexible supporting layer from a second roller, wherein the flexible electronic display layer is unwound at about the same time as the flexible supporting layer.

In some embodiments, the first side of the flexible supporting layer engages the second side of the flexible electronic display layer while passing between the first roller and the second roller during unwinding.

In some embodiments, the method further comprises withdrawing at least a portion of the flexible electronic display layer and at least a portion of the flexible supporting layer through an opening of a housing, wherein the housing contains the first roller and the second roller.

In some embodiments, the method further comprises: winding the flexible electronic display layer around a first roller; and winding the flexible supporting layer around a second roller, wherein the flexible electronic display layer is wound at about the same time as the flexible supporting layer, and wherein the first side of the flexible supporting layer disengages the second side of the flexible electronic display layer during winding.

In some embodiments, the first side of the flexible supporting layer disengages the second side of the flexible electronic display layer while passing between the first roller and the second roller during winding.

In some embodiments, engaging the first side of the flexible supporting layer with the second side of the flexible electronic display comprises: starting from a first configuration where the first side of the flexible electronic display layer is interfaced with the second side of the flexible support layer, rotating the flexible electronic display layer about a side edge to bring the second side of the flexible electronic display layer towards the first side of the flexible supporting layer.

In some embodiments, the method further comprises rotating the flexible electronic, display layer about the side edge so that the second side of the flexible electronic display layer disengages the first side of the flexible supporting layer to return to the first configuration.

Some embodiments disclosed herein are related to a display device comprising: a first roller; a first flexible supporting layer having a first portion wound around the first roller, where the first flexible supporting layer comprises a first side; a second roller; a first flexible electronic display layer having a first portion wound around the second roller, wherein the first flexible electronic display layer comprises a first side configured to emit an image and a second side; and a first housing having a first opening, wherein at least the first roller and the second roller are disposed within the first housing, wherein at least a portion of the first side of the first flexible supporting layer are engaged with at least a portion of the second side on the first flexible electronic display layer, and wherein at least a portion of the first flexible electronic display layer engaged with the first flexible supporting layer extends in a direction from the first roller to the first opening of the first housing.

In some embodiments, the display device further comprises: a third roller; a second flexible supporting layer having a first portion wound around the third roller, wherein the second flexible supporting layer comprises a first side; a fourth roller; and a second flexible electronic display layer having a first portion wound around the fourth roller, wherein the second flexible electronic display layer comprises a first side configured to emit an image and a second side, wherein at least a portion the first side of the second flexible supporting layer is engaged with at least a portion of the second side on the second flexible electronic display layer.

In some embodiments, the first housing further comprises a second opening, wherein the third roller and the fourth roller are disposed within the first housing, and wherein at least a portion of the second flexible electronic display layer engaged with the second flexible supporting layer extends in a direction from the third toiler to the second opening of the first housing,

In some embodiments, the display device further comprises a second housing having a second opening. Wherein the third roller and the fourth roller are disposed within the second housing, and wherein at least: a portion of the second flexible electronic. display layer engaged with the second flexible supporting layer extends in a direction from the third roller to the second opening, of the second housing.

In some embodiments, the second housing is rotatably coupled to first housing.

Some embodiments disclosed, herein provide a method of making a display device, where the method includes: forming a first patterned array of projections on a first side of a flexible supporting layer; and forming a second patterned array of projections on a second side of a flexible electronic display layer, wherein the flexible electronic display layer comprises a first side configured to emit an image, wherein the first patterned array of projections .formed on the first side of the flexible supporting, layer is configured to releasably engage the second patterned array of projections formed on the second side of the flexible electronic display layer to increase stiffness of the flexible electronic display layer.

In some embodiments, at least one of forming the first patterned array of projections and forming the second patterned array of projections, comprises casting, injection molding, or heat pressing.

In some embodiments, the method further comprises engaging at least a portion of the first patterned array of projections on the first side of the flexible supporting layer with at least as portion of the second patterned array of projections on the second side of the flexible electronic display layer.

In some embodiments, the method further comprises fixing a first end of the flexible supporting layer to a first end of the flexible electronic display layer.

In some embodiments, at least one of forming the first patterned array of projections and forming the second patterned array of projections, comprises forming projections having a cylindrical shape, a cuboidal shape, a polyhedral shape a rectangular prism shape, a triangular prism shape, or a hexagonal prism shape.

In some embodiments, at least one of forming the first patterned array of projections and forming the second patterned array of projections, comprises forming projections having straight bands. In some embodiments, at least one of forming the first patterned array of projections and forming the second patterned array of projections, comprises forming projections having a width of about 100 μm to about 5 mm.

In some embodiments, at least one of forming the first patterned array of projections and forming the second patterned array of projections, comprises forming projections having a thickness of about 100 μm to about 5 mm.

In some embodiments, at least one of forming the first patterned array of projections and forming the second patterned array of projections, comprises forming the projections with a material comprising a resin. In some embodiments, the resin comprises one or more of a rubber, a polyester, polystyrene, polytetrafluoroethylene, acrylonitrile butadiene styrene, polyolefins, polyethylene, polypropylene, polyvinyl chloride, polyamide, polyimide, polysulfone, polyetherketone, a liquid crystal polymer, polybenzimidazole, polyurethane, phenol resin, epoxy resin, silicon resin, acrylics, polyethylene terephthalate, a polycarbonate, a polycyclolefin, as polyimide, and copolymers thereof.

In some embodiments, at least one of forming the first patterned array of projections and forming the second patterned array of projections, comprises patterning the array projections in a rhombic lattice, a hexagonal lattice, a square lattice, a rectangular lattice, or a parallelogram-shaped lattice.

In some embodiments, the method further composes rotatably coupling the flexible electronic display layer with the flexible supporting layer.

In some embodiments, the method further comprises: forming a third patterned array of projections on a first side of a second flexible supporting layer; and forming a fourth patterned array of projections on a second side of the flexible supporting layer, wherein the third patterned array of projections on the first side of the second flexible supporting layer is configured to releasably engage a fourth patterned array of projections on a second side of the flexible supporting layer.

In some embodiments, the method further comprises: providing a first roller and a second roller; winding at least a portion of the flexible electronic display layer around the first roller; and winding at least a portion of the flexible supporting layer around the second roller, wherein the display device is configured so that the first patterned array of projections on the flexible supporting layer engages the second patterned array of projections on the flexible electronic display layer while unwinding the flexible electronic display layer from the first roller.

In some embodiments, the method further comprises: providing a housing having at least one opening, wherein the first roller and the second roller are disposed within the housing, and wherein the flexible electronic display layer is configured to be withdrawn from the housing through the opening of the housing.

In some embodiments, the method further comprises: providing at least a partial joining of the flexible electronic display layer and the flexible support layer at one side edge, wherein the display device is configured so that the flexible electronic display layer is rotatable about the side edge to switch between a first configuration where the first side of the flexible electronic display layer is interfaced with the second side of the flexible support layer, and a second configuration where the first patterned array of projections on the first side of the flexible supporting layer is engaged with the second patterned array of projections on the second side of the flexible electronic display layer,

Some embodiments disclosed herein provide a method of making a display device, where the method includes: forming a first patterned array of projections on a first side of a first flexible supporting layer; forming a second patterned array of projections on as second side of a first flexible electronic display layer, wherein the first flexible electronic display layer comprises a first side configured to emit an image; providing a first roller and a second roller; winding at least a portion of the first flexible supporting layer around the first roller; winding at least a portion of the first flexible electronic display layer around the second roller; and providing a first housing having a first opening, wherein at least the first roller and the second roller are disposed within the first housing, wherein at least a portion of the first patterned array of projections on the first flexible supporting layer are engaged with at least a portion of the second patterned array of projections on the first flexible electronic display layer, and wherein at least a portion of the first flexible electronic display layer engaged with the first flexible supporting layer extends in a direction from the first roller to the first opening of the first housing.

In some embodiments, the method further comprises: forming a third patterned array of projections on a first side of a second flexible supporting layer; forming a fourth patterned array of projections on a second side of a second flexible electronic display layer, wherein the second flexible electronic display layer comprises a first side configured as a touchscreen; providing a third roller and a fourth roller; winding a least a portion of the second flexible supporting layer around the third roller; and winding at least a portion of the second flexible electronic display layer around the fourth roller, wherein at least a portion of the third patterned array of projections on the second flexible supporting layer are engaged with at least a portion of the fourth patterned array of projections on the second flexible electronic display layer.

In some embodiments, the method further comprises providing a second opening in the first housing, wherein the third roller and the fourth roller are disposed within the first housing, and wherein at least a portion of the second flexible electronic display layer engaged with the second flexible supporting layer extends in a direction from the third roller to the second opening of the first housing.

In some embodiments, the method further comprises providing a second housing having a second opening, wherein the third roller and the fourth roller are disposed within the second housing, and wherein at least a portion of the second flexible electronic display layer engaged with the second flexible supporting layer extends in a direction from the third roller to the second opening of the second housing.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The foregoing and other features of the present disclosure will become more fully apparent from the following description and appended claims, taken in conjunction with the accompanying drawings. Understanding that these drawings depict only several embodiments in accordance with the disclosure and are not to be considered limiting of its scope, the disclosure will be described with additional specificity and detail through use of the accompanying drawings.

FIG. 1 is a cross-sectional view of one example of a display device that is within the scope of the present application.

FIG. 2 is a cross-sectional view of one example of a display device having two flexible supporting layers that is within the scope of the present application.

FIG. 3 is a cross-sectional view of one example of a display device having two flexible electronic display layers that is within the scope of the present application.

FIG. 4 is a cross-sectional view of one example of a display device having two flexible electronic display layers that is within the scope of the present application.

FIGS. 5A-B are cross-sectional views of one example of a display device having two layers rotatably coupled that is within the scope of the present application.

FIGS. 6A-F are cross-sectional views of one example of a display device that is within the scope of the present application.

FIGS. 7A-D are cross-sectional views of one example of a display device that is within the scope of the present application.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be used, and other changes may be made, without departing from the spirit or scope of the subject matter presented herein. It will be readily understood that the aspects of the present disclosure, as generally described herein, and illustrated in the Figures, can be arranged, substituted, combined., and designed in a wide variety of different configurations, all of which are explicitly contemplated and form part of this disclosure. With respect to the use of any plural and/or singular terms herein, those having skill in the art can translate from the plural to the singular and/or from the singular to the plural as is appropriate to the context and/or application. The various singular/plural permutations may be expressly set forth herein for sake of clarity.

Some embodiments disclosed herein include a display device, The display device can include a flexible supporting layer having a first side, and a flexible electronic display layer. The flexible electronic display layer can include, for example, a first side configured to emit an image and a second side configured to releasably couple with the first side of the flexible supporting layer to increase stiffness of the flexible electronic display layer. The display device can, in some embodiments, advantageously provide a flexible electronic display that can be compactly stored, while also exhibiting increased stiffness when expanded for viewing.

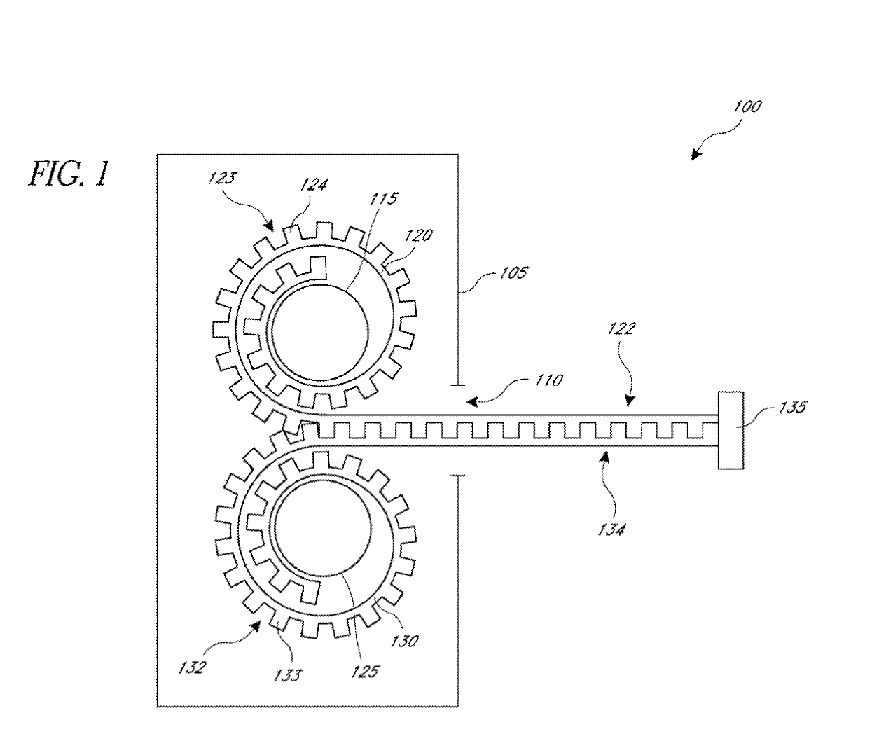

FIG. 1 is a cross-sectional view of one example of a display device that is within the scope of the present application. Display device 100 can include housing 105 having opening 110. First roller 115 can be disposed within housing 100, where flexible electronic display layer 120 is partially wound around first roller 115. As an example, the flexible electronic display layer can include an organic electroluminescent display or an electro-optical display. Flexible electronic display layer 120 can include first side 122 that is configured to emit an image (for example, video or a still image). Flexible electronic display layer 120 can also include second side 123 having projections 124 patterned on second side 123.

Second roller 125 can have flexible supporting layer 130 partially wound around second roller 125. The flexible supporting layer is not particularly limited, and can include, for example, a suitable polymer material including a rubber, a polyester, polystyrene, polytetrafluoroethylene, acrylonitrile butadiene styrene, polyolefins, polyethylene, polypropylene, polyvinyl chloride, polyamide, polyimide, polysulfone, polyetherketone, a liquid crystal polymer, polybenzimidazole, polyurethane, phenol resin, epoxy resin, silicon resin, acrylics, polyethylene terephthalate, a polycarbonate, a polycyclolefin a polyimide, or a combination thereof Flexible supporting layer 130 can include first side 132 having projections 133.

Second side 123 of flexible electronic display layer 120 can be configured to releasably couple first side 132 of flexible supporting layer 130 as portions of the two layers are unwound from first roller 115 and second roller 125. In particular, projections 124 and projections 133 can releasably engage each other to couple the two sides together, For example, projections 124 can be configured in a pattern, and projections 133 can be configured in a complimentary pattern so that the projections interlock. First roller 115 and second roller 125 can be configured so that second side 123 of flexible electronic display layer 120 releasably couples with first side 132 of flexible supporting layer 130 while unwinding from the roller. By coupling the two layers together during unwinding, the stiffness of flexible electronic display layer 120 can be increased when it is removed from housing 100 through opening 110 for viewing. First roller 115 can be configured to rotate about a first axis extending out of the page, and second roller 125 can be configured to rotate about a second axis extending out of the page. The first axis may be generally parallel with the second axis.

Second side 123 of flexible electronic display layer 120 can be fixed to first side 132 of flexible supporting layer 130. As shown in FIG. 1, fastener 135 may fix the two sides together at the end spaced apart from first roller 115 and second roller 125. Fastener 135 may optionally be dimensioned such that fastener 135 cannot fit through opening 110. This configuration can prevent the layers from being completed retracted into housing 100 and/or completely wound onto their respective rollers. In some embodiments, the second side 123 of flexible electronic display layer 120 can be fixed to first side of flexible supporting by an adhesive. First side 122 of flexible electronic display layer 120 can optionally be fixed to first roller 115 at an end adjacent to first roller 115. Similarly, second side 134 of flexible supporting layer 130 can optionally be fixed to second roller 125 at an end adjacent to second roller 125.

One or more of the rollers in the display device (for example, first roller 115 and/or second roller 125 in display device 100 as depicted in FIG. 1) can optionally be spring-loaded. For example, the rollers can include a spring along its axis of rotation that increases tension when a layer is unwound. One or more of the rollers can also include, in some embodiments, a ratchet that prevents the spring-loaded roller from winding-up the layer. The ratchet can be configured so that it can be released (e.g., by manually pressing a button or sliding a switch) when it is desired to retract the layers into the housing. An example of a spring-loaded roller with a ratchet, control is described, in US 2011/0079676, entitled “Retractable Cord Reel”.

The structure of the projections in the flexible supporting layer and flexible electronic display layer are not particularly limited for example, projections 124 and projections 133 as depicted in FIG. 1), Projection shapes can be regular or irregular. Non-limiting, examples of suitable shapes for projections include a cylindrical shape, a cuboidal shape, a polyhedral shape, a rectangular prism shape, a triangular prism shape, and a hexagonal prism shape. The projections can be patterned in various configurations, so long as they can releasably engage. For example, the flexible electronic display layer can include projections that are straight bands extending parallel with troughs disposed between the bands. The flexible supporting layer can also include parallel straight bands that configured to fit within the troughs on the flexible electronic display layer. Similarly, curved bands can be used on both layers that are appropriately spaced to fit into curved troughs. In some embodiments, the projections can be patterned in a two-dimensional lattice, such as a rhombic lattice, a hexagonal lattice, a square lattice, a rectangular lattice, or a parallelogram-shaped lattice. For example, both layers can include cylindrical projections arranged in a hexagonal lattice that will releasably engage. The two-dimension lattice of the projections on the flexible electronic display layer can be the same or different than the two-dimensional lattice of the projections on the flexible supporting layer.

The projections can include a suitable material that imparts some flexibility to releasable engage the two layers, but without significantly deforming. In some embodiments, the projections include a resin. The resin can be, for example, one or more of as rubber, a polyester, polystyrene, polytetrafluoroethylene, acrylonitrile butadiene styrene, polyolefins, polyethylene, polypropylene, polyvinyl chloride, polyamide, polyimide, polysulfone, polyetherketone, a liquid crystal polymer, polybenzimidazole, polyurethane, phenol resin, epoxy resin, silicon resin, acrylics, polyethylene terephthalate, a polycarbonate, a polycyclolefin, a polyimide, and copolymers thereof in some embodiments, the projections can be porous. In some embodiments, the projections can be hollow.

The dimensions of the projections are not particularly limited, The projections can, for example, have a width of at least about 1 nm, at least about 1 μm, at least about 100 μm, at least about 500 μm, or at least about 1 mm. The projections can, for example, have a width of less than or equal to about 5 mm, less than or equal to about 3 mm, less than or equal to about 1 mm, less than or equal to about 500 μm, less than or equal to about 100 μm, or less than or equal to about 1 μm. In some embodiments, the width of the projections can be about 1 nm to about 5 mm, about 100 μm to about 5 mm, or about 1 μm to about 100 μm. The width of the projections on the flexible electronic display layer can be about the same or different than the width of the projections on the flexible supporting layer.

The thickness of the projections is not particularly limited. The projections can, for example, have a thickness of at least about 10 nm, at least about 1 μm, at least about 100 μm, at least about 500 μm, or at least about 1 mm, The projections may, for example, have a thickness of less than or equal to about 5 mm, less than or equal to about 3 mm, less than or equal to about 1 mm, less than or equal to about 500 μm, less than or equal to about 100 μm, or less than or equal to about 1 μm. In some embodiments, the thickness of the projections can be about 10 nm to about 5 mm, or about 1 μm to about 1 mm. The thickness of the projections an the flexible electronic display layer can be about the same or different than the thickness of the projections on the flexible supporting layer,

The projections can, in some embodiments, include an electrorheological fluid or a magnetorheological fluid. For example, the projection can include a resin that forms a cavity containing the electrotheological fluid or a magnetorheological fluid, A suitable electromagnetic field can be applied to increase stiffness and/or adherence of the projections when engaged, Japanese Patent Publication No. 2005-290203 and Tshuchiya, K, et al. “Control of Viscosity Using Redox Reaction,” J. Am. Chem. Soc., 2004, Vol, 12.6(39) pp. 1282-83 suggest suitable fluids for including in the projection. However, the present application is not limited to any particular electrorheological fluid or magnetorheological fluid.

In some embodiments, the projections can include a stimulus-responsive polymer. For example, a gel containing the stimulus-responsive polymer can be disposed within a cavity of the projection. An appropriate electromagnetic field or other stimulus can be applied so that the gel expands when the projections are engaged to increase stiffness and/or adherence. Japanese Patent Publication No. 2006-353034 suggests non-limiting stimulus responsive polymers that can be used in the projections.

Although the display device depicted in FIG. 1 is depicted as containing projections that releasably couple, various other means for releasably coupling the layers can also be used in the alternate or addition to the projections. In some embodiments, one layer can include an adhesive and one layer can include as release surface. For example, referring to FIG. 1, display device 100 can be modified to include an adhesive on second side 123 of flexible electronic display layer 120 instead of projections 124. A release layer can be placed on first side 132 of flexible supporting layer 132 instead of projections 133. The adhesive may releasably adhere to the release surface to couple the flexible electronic display layer and flexible supporting layer as they are unwound from the rollers and withdrawn from the housing. Alternatively, the release layer can be on second side 123 of flexible electronic display layer 120, while the adhesive can be on first side 132 of flexible supporting layer 132. The release surface can, for example, include a siliconized material or a fluoropolymer (for example, polytetrafluoroethylene). The adhesive can be, for example, a pressure-sensitive adhesive, such as a (meth)acrylic polymer.

The flexible supporting layer and flexible electronic display layer can, in some embodiments, be releasably coupled using one or more male engaging members that releasably engage one or more female engaging members. The female engaging members can include concave surface that is configured to receive a convex surface of the male engaging members. As an example, female engaging members and male engaging members can be interlocking discs, such as a snap fastener. The male engaging members can be on the flexible supporting layer, the flexible electronic display layer, or both, The female engaging members can be on the flexible supporting layer the flexible electronic display layer, or both.

In some embodiments, the female engaging members can include one or more loops, and the male engaging members include one or more hooks configured to releasably engage the loops. For example, the layers can have hook-and-loop fasteners (for example, VELCRO) that releasably couple the flexible supporting layer and the flexible electronic display layer.

The flexible supporting layer and flexible electronic display layer can, in some embodiments, be releasably coupled using one or more suction cups. For example, suctions cups can be attached to the flexible supporting layer that can releasably couple with a relatively smooth surface on the flexible electron display layer. The suction cups can be on the flexible supporting layer, the flexible electronic display layer, or both.

The flexible supporting layer and flexible electronic display layer can in some embodiments, be releasably coupled using magnetized regions. For example, the flexible electronic display layer can include magnetized regions having a first polarity, and the flexible supporting layer can include magnetized regions having a second polarity. The magnetized regions having the first polarity may attract the magnetized regions having the second polarity to releasably couple the two layers. The magnetized regions can be formed, for example, with thin bands of ferromagnetic materials in each layer,

In some embodiments, the flexible supporting layer and flexible electronic display layer can be releasably coupled using charged regions. For example, the flexible electronic display layer can include charged regions having a first charge, and the flexible supporting layer can include charged regions having a second charge. The charged regions haying the first charge can attract the charged regions having the second charge to releasably couple the two layers. The charged regions can be formed, for example, with conductive materials (for example, a metal) embedded within an insulating material (for example, an insulating, polymer).

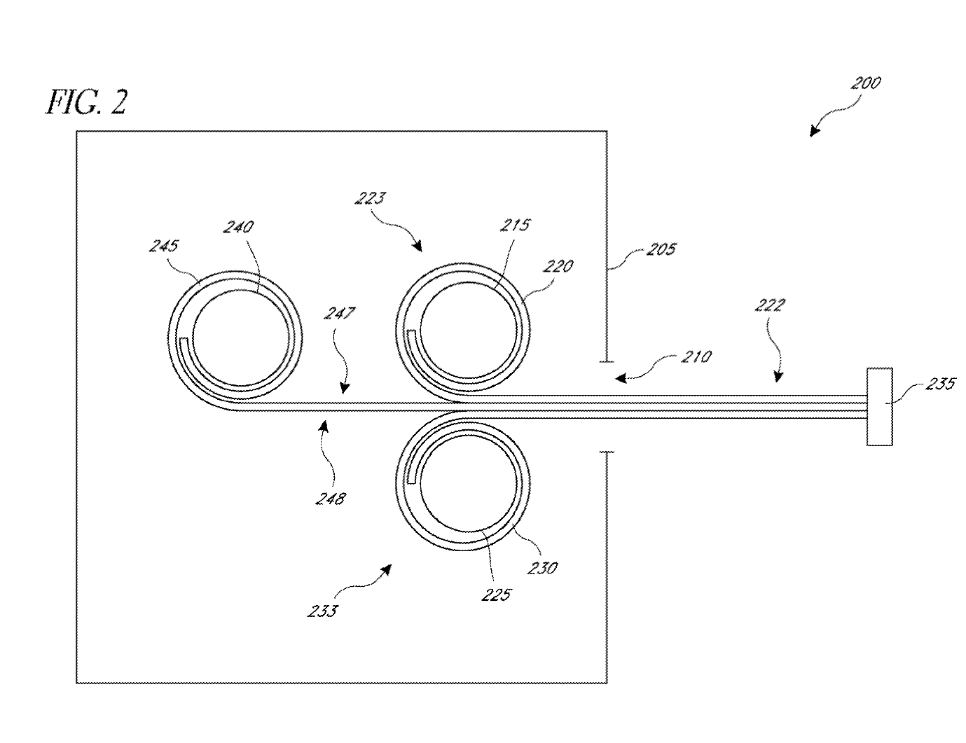

The display device can optionally include two or more flexible supporting layers (for example, two, three, four, five, six or more flexible supporting layers) that releasably couple together to increase stiffness. By including multiple layers, the stiffness may be further increased. FIG. 2 is a cross-sectional view of one example of a display device having two flexible supporting layers that is within the scope of the present application. Display device 200 includes items 205-235 that correspond to items 105-135, respectively, in the display device 100 as depicted in FIG. 1. For example, first roller 215 in display device 200 can generally have the same characteristics as first roller 115 in display device 100. Display device 200 also includes a third roller 240 haying a second flexible supporting layer 245 partially wound around the third roller 240. First side 247 of second flexible supporting layer 245 releasably couples with second side 223 of flexible electronic display layer 220. Second side 248 of second flexible supporting layer 245 releasably couples with first side 233 of flexible supporting layer 230.

As discussed, various approaches for releasably coupling, the layers can be used. As a specific example, second flexible supporting layer 245 can be a fluoropolymer layer having a release surface on both first side 247 and second side 248. Second side 223 of flexible electronic display layer 220 and first side 233 of flexible supporting layer 230 can both include an adhesive that releasably adheres with second flexible supporting layer 245. As another example, the layer can each include projections that releasably couple. The means for releasably coupling the flexible electronic display layer with the second flexible supporting layer can be the same or different than the means for releasably coupling the flexible supporting layer with the second flexible supporting layer.

Second flexible supporting layer 245 can be fixed at one end to flexible electronic display layer 220 and flexible supporting layer 230 by fastener 235. Second flexible supporting layer 245 can be fixed at an opposite end to third roller 240. Third roller 240 may generally have the same characteristics as first roller 215 and/or second roller 225. For example, third roller 240 may be spring-loaded and include a ratchet.

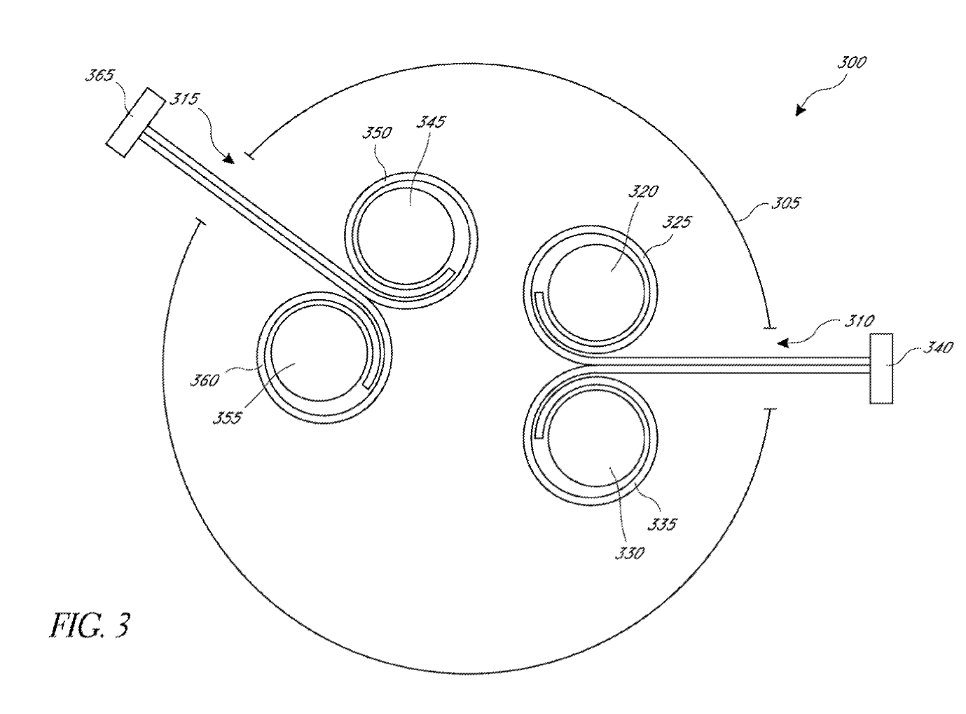

The display device can, in some embodiments, include two or more flexible electronic display layers. FIG. 3 is a cross-sectional view of one example of a display device having two flexible electronic display layers that is within the scope of the present application. Display device 300 includes housing 305 having first opening 310 and second opening 315. First roller 320 has first flexible electronic display layer 325 partially wound around first roller 320. Second roller 330 has first flexible supporting layer 335 partially wound around second roller 330. First flexible electronic display layer 325 can releasably couple with first flexible supporting layer 335 and extend through first opening 310. First flexible electronic display layer 325 can be fixed at one end to first flexible supporting layer 335 by fastener 340.

Third roller 345 has second flexible electronic display layer 350 partially wound around third roller 345. Fourth roller 355 has second flexible supporting layer 360 partially wound around fourth roller 355. Second flexible electronic display layer 350 can releasably couple with second flexible supporting layer 360 and extend through second opening 315. Second flexible electronic display layer 350 can be fixed at one end to second flexible supporting layer 360 by fastener 365.

In some embodiments, at least one of the flexible electronic display layers can function as an input device. For example, first flexible electronic display layer 325 can be a touchscreen. In some embodiments, first flexible electronic display layer 325 can be replaced with an alternative flexible input device, such as a flexible keyboard.

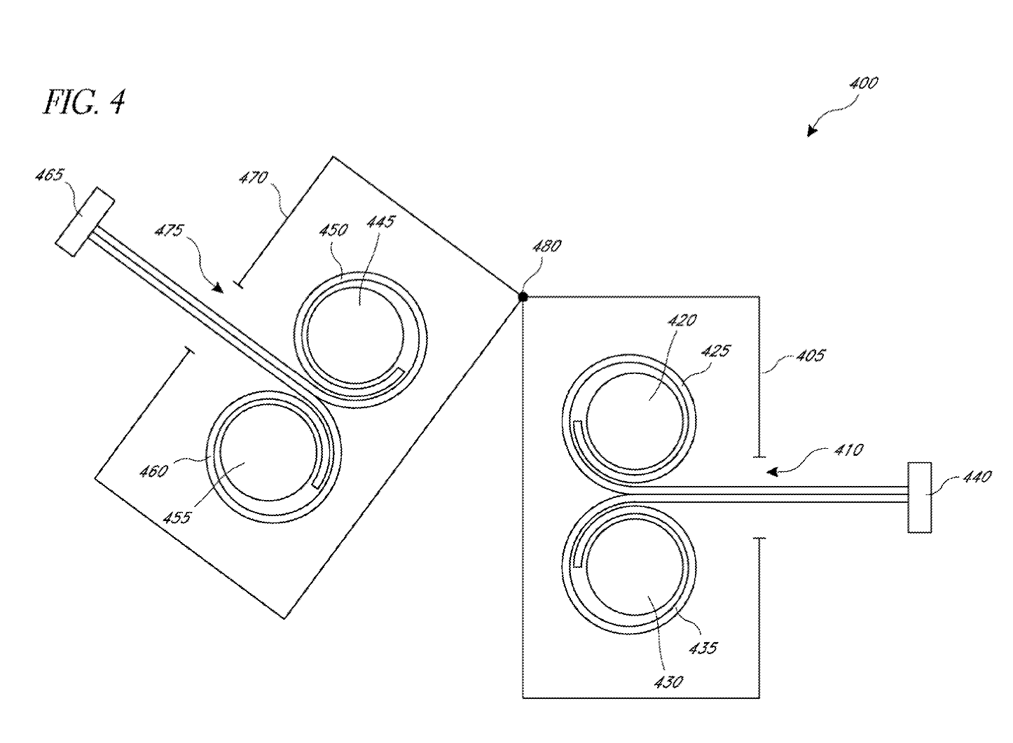

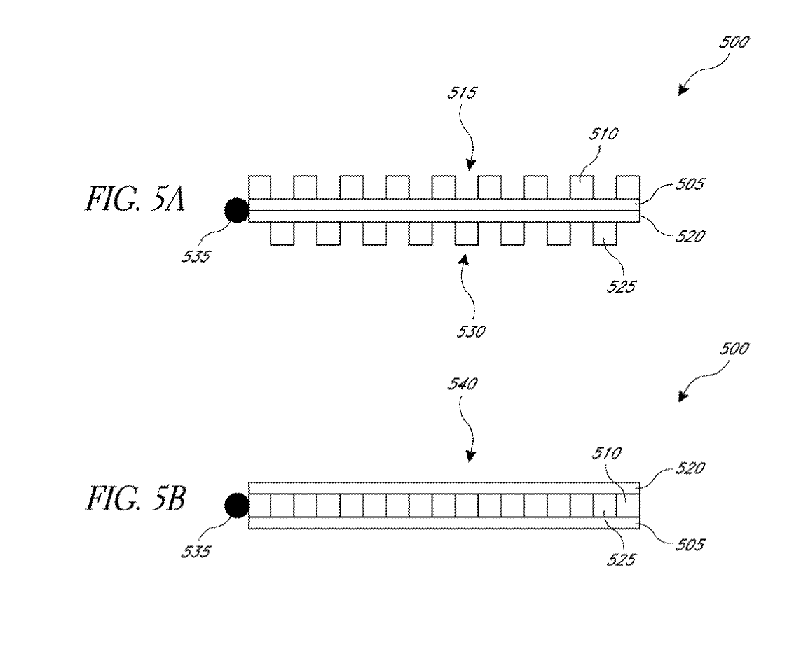

FIG. 4 is a cross-sectional view of one example of a display device having two flexible electronic display layers that is within the scope of the present application. Display device 400 includes items 405, 410, and 420-465 that correspond to items 305, 310, and 320-365, respectively, in the display device 300 as depicted in FIG. 3. For example, third roller 445 in display device 400 can generally have the same characteristics as third roller 345 in display device 300. Third roller 445, second flexible electronic display layer 450, fourth roller 455, and second flexible supporting layer 460 are disposed within second housing 470 having second opening 475. Housing 405 is rotatably coupled to second housing 470 via hinge 480.

FIGS. 5A-B are cross-sectional views of one example of a display device having two layers rotatably coupled that is within the scope of the present application. FIG. 5A shows display device 500 having flexible supporting layer 505 having projections 510 on first side 515 of flexible supporting layer 505. Flexible electronic display layer 520 includes projections 525 on second side 530 of flexible electronic display layer 520. Flexible electronic display layer 520 is rotatably coupled to flexible supporting: layer 505 by hinge 535. FIG. 5B shows display device 500 after rotating flexible supporting layer 505 about hinge 535. Projections 510 and projections 525 are releasably coupled to increase stiffness of flexible electronic display layer 520. An image can be viewed from first side 540 of flexible electronic display layer 520. The skilled artisan, guided by the teachings of the disclosed embodiments, will appreciate that projections in display device 500 can be readily substituted with one or more of the various other means for releasably coupling the layers as described in the disclosed embodiments. For example, a hook-and-loop fastener similar to Velcro may be used instead of the complimentary engaging projections. Similarly, various other alternatives for hinge 535 may be used to rotatably couple the layers. For example, a flexible adhesive tape may be used to rotatably couple the two layers (for example, similar to certain book binding techniques such as tape binding). As another example, a spiral can be threaded through openings in both layers to rotatably couple the two layers.

Some embodiments disclosed herein include a method of using a display device. The method can be used, for example, on the display devices disclosed in the present application (e.g., display device 100 as depicted in FIG. 1). The method can include providing a display device. The display device can include, for example, a flexible supporting layer having a first side; and a flexible electronic display layer having a first side configured to emit an image and a second side configured to releasably couple with the first side of the flexible supporting layer to increase stiffness of the flexible electronic display layer.

The method of using a display device can also include engaging the first side of the flexible supporting layer with the second side of the flexible electronic display layer. Referring to FIGS. 5A-B, the method can be performed, for example, by rotating flexible supporting layer 505 in display device 500 counterclockwise from the configuration in FIG. 5A to the configuration in FIGURE SB As another example, the method can be performed by extending faster 135 in display device 100 as depicted in FIG. 1 away from opening 110 of housing 105. The layers can, in some embodiments, engage while passing between the first, roller and the second roller for example, flexible electronic display layer 120 engages flexible supporting layer 130 while passing between first roller 115 and second roller 125 as depicted in FIG. 1). In some embodiments, the flexible electronic display layer and flexible supporting layer can unwind from the first roller and the second roller, respectively, at about the same time.

The method of using a display device can also include disengaging the first side of the flexible supporting layer from the second side of the flexible electronic. display layer. Referring to FIGS. 5A-B, the method can be performed, for example, by rotating flexible supporting layer 505 in display device 500 clockwise from the configuration in FIG. 5B to the configuration in FIG. 5A. As another example, the method can be performed winding flexible electronic display layer 120 about first roller 115 in display device 100 as depicted in FIG. 1 such that fastener 135 moves toward opening 110 of housing 105. The layers can, in some embodiments, disengage while passing between the first roller and the second roller. In some embodiments, the flexible electronic display layer and flexible supporting layer can wind about the first roller and the second roller, respectively, at about the same time.

Some embodiments disclosed herein include a method of making a display device. The method can be used to make display devices disclosed in the present application (for example, display device 100 as depicted in FIG. 1). The method can include, in some embodiments, forming a first patterned array of projections on a first side of a flexible supporting layer; and forming a second patterned array of projections on a second side of a flexible electronic display layer. The flexible electronic display layer can include a first side configured to emit an image. In some embodiments, the first patterned array of projections formed on the first side of the flexible supporting layer is configured to releasably engage the second patterned array of projections formed on the second side of the flexible electronic display layer to increase stiffness of the flexible electronic display layer.

The patterned array of projections can be formed, for example, using one or more of casting, injection molding. UV imprinting, and heat pressing. The patterned array of projections can generally have the same characteristic as described above with regard to the display device. For example, the projections can have a width of about 1 nm to about 5 mm, or about 100 μm to about 5 mm. The patterned array of projections can include straight bands and/or non-straight bands for example, curved bands).

The method of making a display device can optionally include engaging at least a portion of the first patterned array of projections on the first side of the flexible supporting layer with at least a portion of the second patterned array of projections on the second side of the flexible electronic display layer. The method can also include, in some embodiments, fixing a first end of the flexible supporting layer to a first end of the flexible electronic display layer.

In some embodiments, the method of making a display device can include rotatably coupling the flexible electronic display layer with the flexible supporting layer. For example, the layers can have the same configuration as display device 500 as depicted in FIGS. 5A-B. The layers can be rotatably coupled by fixing the layers with a hinge, flexible adhesive tape, spiral, or the like.

In some embodiments, the method of making a display device can include at least partially winding the flexible electronic display layer and the flexible supporting layer about a first roller and a second roller, respectively. For example, the layers can be wound around rollers in the same configuration as display device 100 as depicted in FIG. 1. As such, the method can include providing a first roller and a second roller; winding at least a portion of the flexible electronic display layer around the first roller; and winding at least a portion of the flexible supporting layer around the second roller. The display device can be configured so that the first patterned array of projections on the flexible supporting layer engages the second patterned array of projections on the flexible electronic display layer while unwinding the flexible electronic display layer from the first roller. The first roller, second roller, flexible electronic display layer, and flexible supporting layer can optionally be disposed in a housing having at least one opening. The flexible electronic display layer can be configured to be withdrawn through the opening of the housing.

The method of making a display device can also include forming a second flexible electronic display layer and a second flexible supporting layer. For example, the method can form display device 300 as depicted in FIG. 3. As such, the method can also include forming a third patterned array of projections on a first side of a second flexible supporting layer; and forming a fourth patterned array of projections on a second side of the flexible supporting layer, The third patterned array of projections on the first side of the second flexible supporting layer can be configured to releasably engage a fourth patterned array of projections on a second side of the flexible supporting layer.

The first roller, second roller, flexible electronic display layer, flexible supporting layer, the third roller, the fourth roller, the second flexible electronic display layer, and the second flexible supporting layer can optionally be disposed in a housing that includes at least two openings. The flexible electronic display layer can be configured to be withdrawn through the first opening of the housing, while the second flexible electronic display layer can be configured to be withdrawn through tile second opening of the housing.

In some embodiments, the first roller, second roller, flexible electronic display layer, and flexible supporting layer can be disposed in a first housing have at least one opening. The flexible electronic display layer can be configured to be withdrawn through the first opening of the housing. The third roller, the fourth roller, the second flexible electronic display layer, and the second flexible supporting layer may optionally be disposed in a second housing that includes at least one opening. The second flexible electronic display layer can be configured to be withdrawn through the first opening of the housing. In some embodiments, the first housing and second housing can be rotatably coupled. For example, the both housing can be attached to a common hinge.

### EXAMPLES

Additional embodiments are disclosed in further detail in the following examples, which are not in any way intended to limit the scope of the claims

### Example1

### Making and Using a Display Device

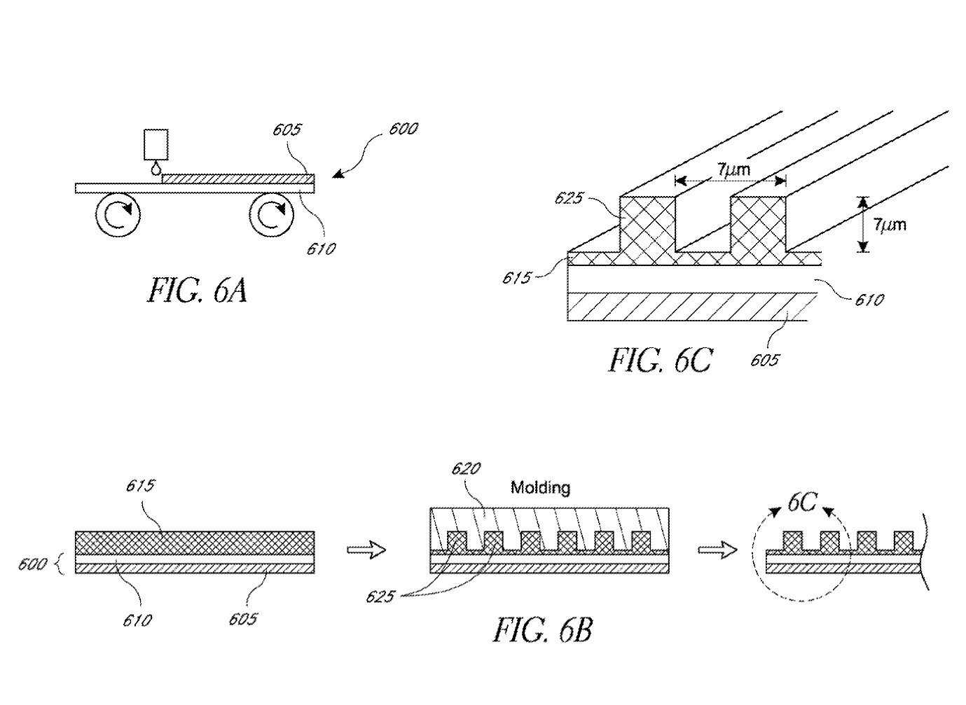

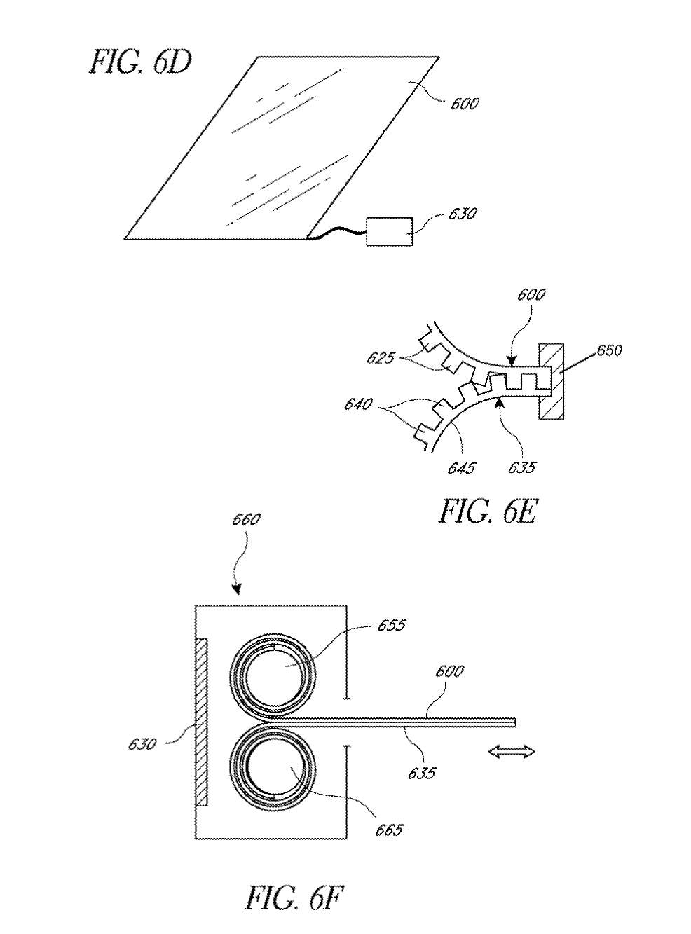

With reference to FIG. 6A, a display device is fabricated by printing an organic light-emitting diode (“GEED”) layer 605, for example using “printed electronics technology” known in the art screen printing, flexography, gravure, offset lithography, inject printing, etc.) on a flexible polymeric film 610 (e.g., polyethylene naphthalate (PEN) film), to result in a flexible OLED display layer 600. The flexible OLED display layer 600 may have a thickness of about 100 μm),

As shown in FIGS. 6B and 6C, on the back side (second side) of the flexible OLED display layer 600, line- and space-type projections 625 made of an elastomeric material 615, e.g., rubber, are fabricated. The projections 625 have a pitch of 7 μm and a depth of 7 μm. The projections 625 are, for example, formed by pressing a mold 620 into a layer of the elastomeric material 615.

As illustrated in FIG. 6D, the flexible OLED display layer 600 is connected to a driver circuit and battery 630. A supporting layer 635 including an array of projections 640 (e.g., molded on a flexible PEN film 645, as described above for the display layer) is also made as shown in FIG. 6E. The array of projections 640 on the supporting layer 635 is complementary to the array of projections 625 on the display layer. As shown in FIG. 6E, the display layer 600 and the supporting layer 635 are bound at the edge 650 so that the projections are aligned to engage with each other.

As shown in FIG. 6F, the flexible GEED display layer 600 and the supporting layer 635 are wound separately onto rollers 655 and 665, respectively, within a housing 660. The rollers have springs and a releasable ratchet (not illustrated). A driver circuit and battery 670 may be fixed in the housing 660.

To use the display device, the flexible OLED display layer 600 and the supporting layer 635 are unwound from the rollers 655 and 665, respectively, and withdrawn from the housing 660 to fully extend the display device for use. The projections 625 on the flexible OLED display layer 600 and the projections 640 on the supporting layer 635 are engaged to increase stiffness of the display device.

When the display device is stored, the ratchet is released. The spring rotates the rollers to retract the display layer 600 and the supporting layer 635 into the housing 660. The projections 625 on the display layer 600 and the projections 640 on the supporting layer 635 are disengaged in the process so that the two layers are wound up to the rollers 655 and 665 and stored in the housing 660.

### Example 2

### Making and Using a Display Device

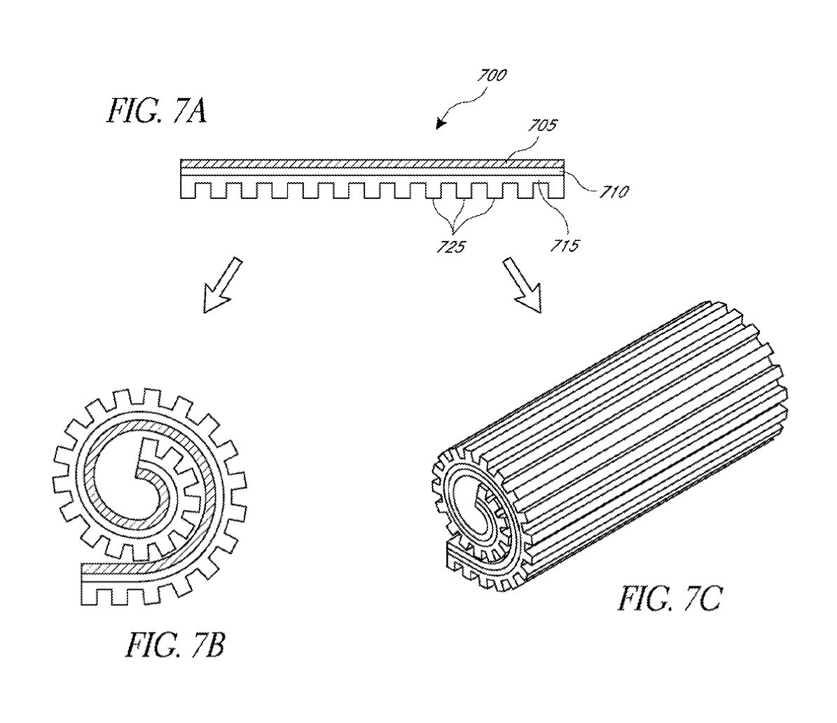

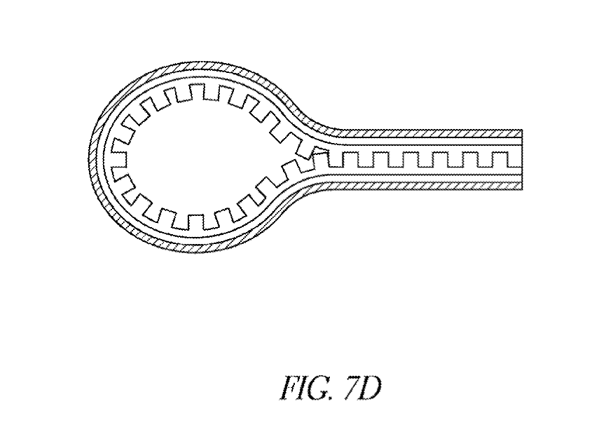

A flexible OLED display layer 700 with a thickness of about 100 μm is fabricated as described in EXAMPLE 1 by printing an OLED layer 705 on a polyethylene naphthalate (PEN) film 710 as shown in FIG. 7A. On the back side of flexible display layer 700, a rubber layer 715 with molded line- and space-type projections 725 having a pitch of 1 mm and depth of 1 mm are fabricated.

When not in use, the flexible OLED display layer 700 of the display device may be wounded up like a roil as illustrated in FIGS. 7B and C. To use the display device, the display layer 700 may be unrolled and folded on itself as shown in FIG. 7D, such that the back sides of the flexible OLED display layer 700 including the line- and space-type projections 725 are folded towards each other until the projections 725 engage to stiffen the display device. Thus, one section on the back side can comprise a patterned array of projections 725 which engages with the patterned array of projections 725 on another section on the back side. It will be appreciated that the back sides of the flexible OLED display layer 700 can engage to stiffen the display device according to any combination of the embodiments disclosed herein, including but not limited to a release surface and adhesive, male and female engaging members, suction cups, magnetized regions, and charged regions. For example, one section on the back side of the OLED display layer 700 can comprise male members, and another section on the back side of the OLED display layer 700 can comprise female members. In some embodiments, when the back sides of the display layer 700 are folded toward each other, the male and female members may engage each other to stiffen the display device 700.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing, only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. in addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together. A and C together, B and C together, and/or A, B, and C together, etc.). In those instances where a convention analogous to “at least one of A, B, or C, etc,” is used, in general such a construction is intended in the sense one haying skill in the all would understand the convention (e.g., “a system having at least one of A, B, or C” would include but not be limited to systems that have A alone, B alone, C alone, A and B together, A and C together, B and C together and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

Mini As will be understood by one skilled in the art, for any and all purposes, such as in terms of providing a written description, all ranges disclosed herein also encompass any and all possible sub-ranges and combinations of sub-ranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into sub-ranges as discussed above. Finally, as will be understood by one skilled in the art, a range includes each individual member. Thus, for example, a group having 1-3 articles refers to groups having 1, 2, or 3 articles. Similarly, a group having 1-5 articles refers to groups having 1, 2, 3, 4. or 5 articles, and so forth.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into .fewer steps and operations, or expanded into additional steps and operations without detracting from the essence of the disclosed embodiments.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

1. A display device comprising:
a flexible electronic display layer comprising:
a first side configured to emit an image; and
a second side comprising a first section configured to releasably couple a second section.
a flexible supporting layer comprising:
a first side comprising the second section, wherein the second side of the flexible electronic display layer is configured to releasably couple with the first side of the flexible supporting layer to increase stiffness of the flexible electronic display layer.

2. (canceled)

3. (canceled)

4. The display device of claim 1, wherein
at least one of the first section on the second side of the flexible electronic display layer and the second section on the first side of the flexible supporting layer comprises a release surface; and
at least one of the first section on the second side of the flexible electronic display layer and the second section on the second side of the first side of the flexible supporting layer comprises an adhesive.

5. The display device of claim 4, wherein the release surface is siliconized.

6. The display device of claim 4, wherein the release surface comprises a fluoropolymer.

7. The display device of claim 4, wherein the adhesive is a pressure-sensitive Adhesive.

8. The display device of claim 1, wherein:
at least one of the first side of flexible supporting layer and the second side of flexible display layer comprises one or more male engaging members; and
at least one of the first side of flexible supporting layer and the second side of flexible display layer comprises one or more female engaging member configured to releasably engage the one or more male engaging members, wherein the one or more female engaging, members comprise one or more loops, wherein the one or more male engaging members comprise one or more hooks configured to releasable engage the one or more loops.

9. (canceled)

10. (canceled)

11. (canceled)

12. The display device of claim 1, wherein the first side of flexible supporting layer comprises one or more suction cups configured to releasably adhere the second side of flexible electronic display layer.

13. (canceled)

14. The display device of claim 1, wherein:
the first side of flexible supporting layer comprises one or more first magnetized regions having a first polarity;
the second side of flexible electronic display layer comprises one or more second magnetized regions having a second polarity; and
the first magnetized regions on the first side of flexible supporting layer are configured to releasably couple with the second magnetized regions on the second section side of flexible electronic display layer.

15. The display device of claim 1, wherein:
the first side of flexible supporting layer comprises one or more first chanted regions having a first charge;
the second side of flexible electronic display layer comprises one or more second charged regions having a second charge; and
the first charged regions on the first side of flexible supporting layer are configured to releasably couple with the second charged regions on the second side of flexible electronic display layer.

16. The display device of claim 1, wherein the first side of flexible supporting layer comprises a first patterned array of projections and the second side of flexible electronic display layer comprises a second patterned array of projections, wherein the first array of projections is configured to releasably engage the second patterned array of projections to increase stiffness of the flexible electronic display layer, wherein at least one of the first patterned array of projections and the second patterned array is or hollow projections.

17. (canceled)

18. (canceled)

19. (canceled)

20. (canceled)

21. (canceled)

22. (canceled)

23. (canceled)

24. (canceled)

25. (canceled)

26. (canceled)

27. The display device of claim 16, wherein at least one of the first patterned array of projections and the second patterned array of projections have projections comprising an electrorheological fluid or a magnetorheological fluid encapsulated in a resin.

28. The display device of claim 16, wherein at least one of the first patterned array of projections and the second patterned array of projections have a rhombic lattice, a hexagonal lattice, a square lattice, a rectangular lattice, or a parallelogrammic.

29. The display device of claim 28, wherein the first patterned array of projections has about the same lattice as the second patterned array of projections.

30. (canceled)

31. (canceled)

32. (canceled)

33. The display device of claim 1, wherein the flexible electronic display layer and the flexible supporting layer are rotatably coupled about a hinge.

34. The display device of claim 1, further comprising:
a first roller, wherein the flexible electronic display layer is at least partially wound around the first roller;
a second roller, wherein the flexible supporting layer is at least partially wound around the second roller, wherein the display device is configured so that the first section on the second side of the flexible electronic display layer engages the second section on the first side of the flexible supporting layer while unwinding the flexible electronic display layer from the first roller, and
a housing haying at least one opening, wherein the first roller and the second roller are disposed within the housing and wherein the flexible electronic display layer is configured to be withdrawn from the housing through the opening of the housing,
wherein the flexible electronic display layer and the flexible supporting layer are at least partially joined at one side edge so that the flexible electronic display layer is rotatable about the side edge to switch between a first configuration where the first side of the flexible electronic display layer is interfaced with a second side of the flexible support layer, and a second configuration where the first side of the flexible supporting layer is engaged with the second side of the flexible electronic display layer.

35. (canceled)

36. (canceled)

37. (canceled)

38. (canceled)

39. (canceled)

40. (canceled)

41. (canceled)

42. (canceled)

43. A method of using a display device, the method comprising:
providing a display device comprising:
a flexible electronic display layer comprising:
a first side configured to emit an image; and
a second side comprising a first section configured to releasably couple a second section; and
a flexible supporting layer comprising a first side, wherein the first side of the Flexible supporting layer comprises the second section; and
engaging the first section on the second side of the flexible electronic display with the second section on the first side of the flexible supporting layer to increase stiffness of the flexible electronic display layer.

44. (canceled)

45. (canceled)

46. (canceled)

47. The method of claim 46,
wherein engaging the first section on the second side of the flexible electronic display layer with the second section on the first side of the flexible supporting layer comprises:
unwinding the flexible electronic display layer from a first roller; and
unwinding the flexible supporting layer from a second roller, wherein the flexible electronic display layer is unwound at about the same time as the flexible supporting liner.

48. The method of claim 47, wherein the first section on the second side of the flexible electronic display layer engages the second section on the first side of the flexible supporting layer while passing between the first roller and the second roller during unwinding.

49. The method of claim 47 further comprising withdrawing at least a portion of the flexible electronic display layer and at least a portion of the flexible supporting layers through an opening of a housing, wherein the housing contains the first roller and the second roller.

50. The method of claim 43, further comprising:
winding the flexible electronic display layer around a first roller; and
winding the flexible supporting layer around a second roller, wherein the flexible electronic display layer is wound at about the same time as the flexible supporting layer, and wherein first section on the second side of the flexible electronic display layer disengages the second section on the first side of the flexible supporting layer during winding.

51. The method of claim 50, wherein the first section on the second side of the flexible electronic display layer disengages the second section on the first side of the flexible supporting layer while passing between the first roller and the second roller during winding.

52. The method of claim 43, wherein engaging the first section on the second side of the flexible electronic display layer with the second section on the first side of the flexible supporting layer comprises:
starting from a first configuration where the first side of the flexible electronic display layer is interfaced with the second side of the flexible support layer, rotating the flexible electronic display layer about a side edge to bring the second side of the flexible electronic display layer towards the first side of the flexible supporting layer.

53. The method of claim 52, further comprising rotating the flexible electronic display layer about the side edge so that the second section on the first side of the flexible supporting layer disengages the first section on the second side of the flexible electronic display layer to return to the first configuration.

54. (canceled)

55. (canceled)

56. (canceled)

57. (canceled)

58. (canceled)

59. A method of making a display device, the method comprising:
forming a first patterned array of projections on a first side of a flexible supporting layer;
forming a second patterned array of projections on the second side of the flexible electronic display layer, wherein the flexible electronic display layer comprises a first side configured to emit an image, wherein the first patterned array of projections formed the first side of flexible supporting layer is configured to releasably engage the second patterned array of projections formed on the second side of the flexible electronic display layer to increase stiffness of the flexible electronic display layer.

60. (canceled)

61. (canceled)

62. The method of claim 59, wherein at least one of forming the first patterned array of projections and forming the second patterned array of projections, comprises casting, injection molding, or heat pressing.

63. (canceled)

64. (canceled)

65. (canceled)

66. (canceled)

67. (canceled)

68. (canceled)

69. (canceled)

70. (canceled)

71. (canceled)

72. The method of claim 59, further comprising rotatably coupling the flexible electronic display layer with the flexible supporting layer.

73. (canceled)

74. The method of claim 59, further comprising:
providing a first roller and a second roller;
winding at least a portion of the flexible electronic display layer around the first roller;
winding at least a portion of the flexible supporting layer around the second roller, wherein the display device is configured so that the first patterned array of projections on the first section on the flexible electronic display layer engages the second patterned array of projections on the second section;
providing a housing haying at least one opening, wherein the first roller and the second roller are disposed within the housing, and wherein the flexible electronic display layer is configured to be withdrawn from the housing through the opening of the housing; and
providing at least joining of the flexible electronic display layer and the flexible support layer at one side edge, wherein the display device is configured so that the flexible electronic display layer is rotatable about the side edge to switch between a first configuration where the first side of the flexible electronic display layer is interfaced with the second side of the flexible support layer, and a second configuration where the first patterned array of projections on the first section on the second side of the display layer is engaged with the second patterned array of projections on the second section.

75. (canceled)

76. (canceled)

77. (canceled)

78. (canceled)

79. (canceled)

80. (canceled)
